(19) United States
(12) Patent Application Publication
(10) Pub. No.: US 2010/0033181 A1
(43) Pub. Date: Feb. 11, 2010

(54) Levitating MEMS Resonator for Magnetic Resonance Force Microscopy

(75) Inventor: Mark A. Jupina, Harleysville, PA (US)

Correspondence Address: FLASTER/GREENBERG P.C.;Four Penn Center, 1600 John F. Kennedy Boulevard, 2nd Floor, PHILADELPHIA, PA, 19103, US

(73) Assignee: Villanova University, Villanova, PA (US)

(21) Appl. No.: 12/537,800

(22) Filed: Aug. 7, 2009

Related U.S. Application Data
(60) Provisional application No. 61/188,145, filed on Aug. 7, 2008.

(51) Int. Cl. G01R 33/48; G01R 33/44

(52) U.S. Cl. 324/309; 324/318

(57) ABSTRACT

A self-stabilized, levitating MEMS (Micro Electro-Mechanical Systems) resonator is provided for detection of magnetic resonance spectra of electrons and nuclei in magnetic resonance force microscopy (MRFM) measurements. The present MRFM system includes a levitating micro-disk having electrically-controlled force sensitivity. To achieve imaging on the scale of a single nuclear spin, the force sensitivity of the measurement must be on the order of 1 aN (atto-Newton) or less. For about a 1 aN force to produce deflections comparable to an angstrom for interferometer detection, the stiffness or spring constant (k) of the resonator will typically be less than 1 μN/m (micro-Newtons per meter). Since the resonator is to be driven with an oscillating force at its resonance, there is a quality-factor (Q) enhancement of the amplitude of the motion. As a result, the k/Q ratio is preferably less than 1×10⁻⁸ N/m and is achievable with the contemplated levitating micro-disk resonator.

### RELATED APPLICATION

The present application claims the benefit of the filing date of U.S. Provisional Application No. 61/188,145, file Aug. 7, 2008, which is herein incorporated by reference.

### BACKGROUND

In Magnetic Resonance Force Microscopy (MRFM), a small sample is suspended on a micro-machined cantilever near a ferromagnetic tip whose shape creates an inhomogeneous magnetic field. The nuclear spins in the sample are polarized by the inhomogeneous magnetic field. A second, oscillating magnetic field is applied by an RF coil, which excites a spin resonance in the atoms in those regions of the sample where the magnetic resonance condition is met. By slow frequency or amplitude modulation of the RF field, a modulation in the nuclear magnetization of the resonant fraction of the sample occurs, leading to a modulation in the force between the sample and the magnetic tip. This force produces a measurable oscillation in the deflection of the cantilever, which is detected with an optical-fiber interferometer.

In the development of MEMS (micro-electromechanical systems) devices, it is desirable that the proof mass and any other portion of the device do not come into mechanical contact with one another. Once the proof mass is levitated, there should be no need for feedback control and, thereby, this MEMS device should be considered as self-levitating. The apparent advantages of a non-contact, self-levitating MEMS device are three fold. First, the substantial reduction in the mechanical wear of the structures leads to greater reliability and overall lifetime. Second, the reduction in loss mechanisms leads to lower power devices that could be used in energy scavenging applications or “green” technologies. Third, the restoring force and thereby the “electrical” spring constant (k_{elec}) of the device can be tuned electrically.

An attractive force through the application of an electrostatic field is employed to levitate a micro-disk in the contemplated device. However, Eamshaw's theorem [1] indicates that it is not possible to achieve static levitation, i.e., stable suspension of an object against gravity, using any combination of fixed magnets and electric charges. Thereby, stable suspension in the contemplated device is achieved by repulsive electromagnetic forces that arise between RF excitation currents applied in coils within the device and eddy currents generated within the micro-disk through Lenz's law. Prior embodiments for the static levitation of objects have implemented feedback control to stabilize the position of the sensing object in inertial sensing applications [2, 3] and in MRFM detection [4]. In one other embodiment [5], electromagnetic forces were employed to levitate a disk while electrostatic forces were used for stabilization of the disk's position.

Rugar's group at IBM used MRFM technology in the summer of 2004 to detect the signal from a single electron spin at a silicon dangling bond center (known as an E′ center) in gamma irradiated vitreous silica (Suprasil W2) at a temperature of 1.6 K in a small vacuum chamber with micro-cantilevers [6]. At least three orders of magnitude improvement in the force sensitivity is still required to image single protons in a reasonable amount of time. Improvements to enhance the MRFM measurement sensitivity have involved to a large degree only a refinement in the cantilever technology.

The central feature of a magnetic resonance force microscope is the mechanical microscopic cantilever. The cantilever's spring constant (k) is typically about 100 μN/m (micro-Newtons per meter). To achieve imaging on the scale of a single nuclear spin, the force sensitivity of the measurement must be improved by roughly three orders of magnitude. Such an improvement can be achieved if the resonating cantilever is replaced by a relatively low force constant oscillator. For a single proton, the force is about 1.4×10⁻¹⁸ N or 1.4 aN (atto-Newtons). For about a one aN force to produce deflections comparable to an angstrom for interferometer detection, the stiffness or spring constant of the cantilever is preferably less than 1 μN/m. Since the cantilever is to be driven with an oscillating force at its resonance, there is a quality-factor (Q) enhancement of the amplitude of the motion. As a result, the k/Q ratio is preferably less than 1×10⁻⁸ N/m.

### SUMMARY OF THE INVENTION

The present invention relates to a micro electromechanical resonator devised in a Magnetic Resonance Force Microscopy (MRFM) system. The system resonator comprises a levitating micro-disk, wherein measurements of force variations are conducted between the micro-disk and a levitated sample. The force sensitivity of the micro-disk is electrically-controlled and the micro-disk is levitated by the application of an electrostatic field at self-stabilized equilibrium due to application of repulsive electromagnetic forces. The electrostatic field is introduced by positioning of electrodes (DC biased) that lifts the disk while eddy currents create a restoring force on the disk to stabilize levitation. The electrodes induce RF magnetic fields to satisfy sample spin resonance in order to achieve imaging on the scale of a single nuclear spin at a desired force sensitivity and at a desired ratio of spring constant (k) to the quality factor (Q) of the resonating micro-disk. Measurement is conducted on the amplitude of the lateral oscillations of the micro-disk generated by forces applied on the disk by the sample.

In a further embodiment, a multi-segmented coil electrode may be used to rotate a disk for cross-sectional sample exposure. Further, DC biased electrodes may be replaced with an off-chip or on-chip RF wire to apply an RF magnetic field. A combination of RF current and DC bias are injected from positions on the coil to stabilize the micro-disk. Measurement of force effects on the disk are conducted on a longitudinal axis, as the disk oscillates in an end to end rocking motion like a see-saw.

### BRIEF DESCRIPTION OF THE DRAWINGS

For the purposes of illustrating the invention, the drawings show various forms of the invention. The invention is not, however, limited to the precise forms shown, unless such limitations are expressly incorporated into the claims.

FIG. 1 shows a top perspective view of an embodiment of the contemplated invention.

FIG. 2 shows a top plan view of the embodiment shown in FIG. 1, but without a test sample included.

FIG. 3 shows a partial cross-sectional view of one-half of the contemplated embodiment, with the section taken in the x-z plane (FIG. 1) at the location shown in FIG. 2.

FIG. 4 shows a partial cross-sectional view of one half of the contemplated embodiment, with the section taken in the y-z plane (FIG. 1) at the location shown in FIG. 2.

FIG. 5 shows a simplified cross-sectional view of one-half of the contemplated embodiment as taken in the x-z plane (FIG. 1), with certain elements being removed for clarity and with the electric field lines around the DC bias electrode shown from a COMSOL Multi-Physics simulation.

FIGS. 6a and 6b show cross-sectional views of one-half of the contemplated embodiment taken in the x-z plane (FIG. 1), with certain elements being removed for clarity. FIG. 6a shows the RF magnetic field lines at 100 MHz around the inner and outer RF current coils from a COMSOL Multi-Physics simulation. FIG. 6b shows the repulsive forces on the surfaces of the micro-disk portion, with the repulsive forces depicted as arrows and with the size of the arrow representing the relative magnitude of the force.

FIGS. 7a and 7b show cross-sectional views of one-half of the contemplated embodiment taken in the x-z plane (FIG. 1), with certain elements being removed for clarity. FIG. 7a shows the RF magnetic field lines at 100 MHz around the inner and outer RF current coils from a COMSOL Multi-Physics simulation. FIG. 7b shows the repulsive forces on the surfaces of the micro-disk portion, with the repulsive forces depicted as arrows and with the size of the arrow representing the magnitude of the force.

FIG. 8 shows a diagrammatic perspective view of one embodiment of a micro-disk portion of the contemplated invention.

FIG. 9a shows a multi-segmented coil embodiment. FIG. 9b shows the current signals for the multi-segmented coil for creating a counter-clockwise rotation of the micro-disk. FIG. 9c the current signals for the multi-segmented coil for creating a clockwise rotation of the micro-disk.

### DETAILED DESCRIPTION

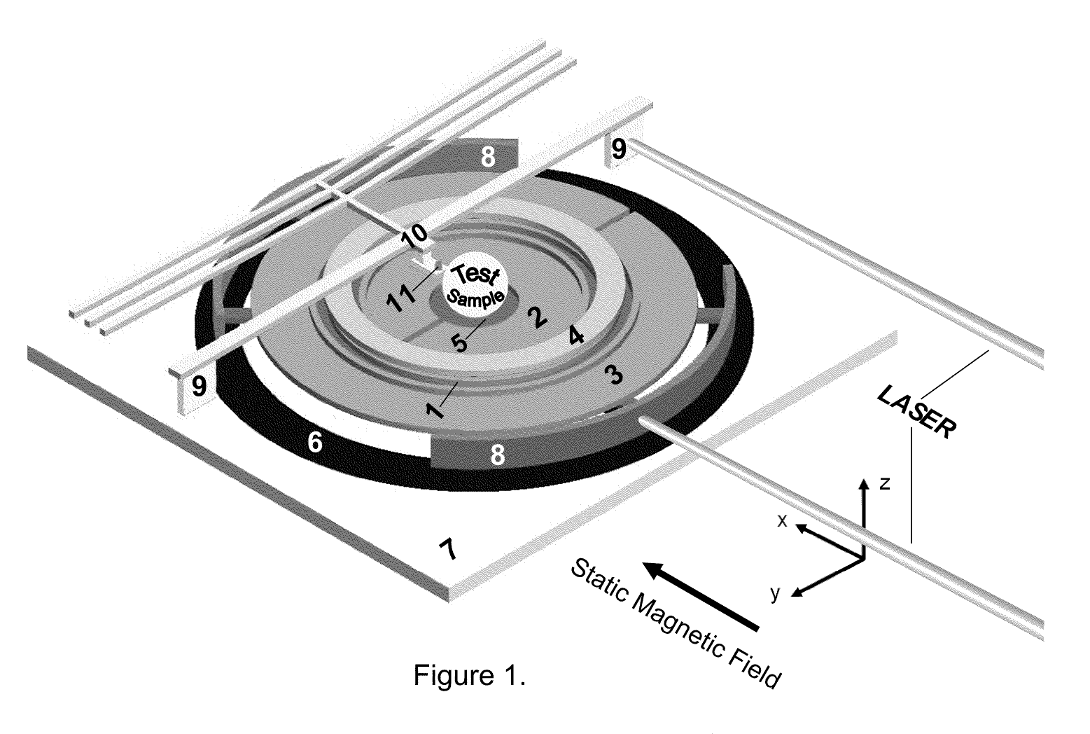

In the drawings, where like numerals identify like elements, there is shown an embodiment of a device in accordance with the present invention. In FIG. 1 the device is illustrated with a test sample included. A DC or static magnetic field is shown to be applied along the x-direction. Laser beams in an interferometer measurement are shown to detect the x-axis motion of the levitated disk (via the motion of the reflector) and the micro-positioner (via the motion of the reflector). The objects in the diagrammatic view are labeled as follows:
1. DC bias electrode that applies an electrostatic field to levitate the micro-disk.
2. Inner RF current coil that applies a stabilizing force to achieve static levitation.
3. Outer RF current coil that applies a stabilizing force to achieve static levitation.
4. Shield electrode for DC bias electrode.
5. Levitating micro-disk.
6. Ground or reference plane.
7. Ceramic substrate.
8. Micro-disk reflector for interferometer measurement.
9. Micro-positioner reflector for interferometer measurement.
10. Bent-beam electro-thermal actuator (micro-positioner) to provide placement of the ferromagnetic sample relative to the test sample.
11. Ferromagnetic sample to generate the magnetic field gradient.

The MRFM system that is shown in FIG. 1 includes a levitating micro-disk with a test sample to be imaged and a ferromagnetic sample, such as Fe—Co (iron-cobalt) alloy, Sm—Co (samarium-cobalt) alloy or Ni—Co (nickel-cobalt) alloy, deposited on a micro-positioner (a bent-beam electro-thermal actuator [7] is shown). The levitating disk is contemplated to have a thickness of 4 μm and a radius of 100 μm. Other geometries (thicknesses and radii) of the disk are possible depending on the skin depth of the metal at the excitation frequency used, and the size of the sample to be imaged. Test sample particles with radii as large as about 20 μm could be used in the illustrated device in FIG. 1. Other types of micro-positioners involving electrostatic or piezoelectric actuation could also be used to position the ferromagnetic sample with respect to the test sample to set the magnetic field gradient and the position of the resonant slice (the region that satisfies the spin resonance condition) within the test sample. Other possible configurations (not illustrated here) could involve mounting a test sample on a micro-positioner and depositing a ferromagnetic material on the levitating disk. Additional supports, constraints and wires that would be normally included in an actual fabricated device are not shown in FIG. 1, to simplify the illustration.

For the illustrated device in FIG. 1, a fabrication process involving the deposition of nine-to-ten non-ferromagnetic metal layers (such as copper or gold) and one ferromagnetic metal layer (such as Fe—CO, SM-Co, or Ni—Co alloy) is contemplated. Each deposited metal layer is contemplated to be about 4 μm thick. Depending on the complexity of an actual fabricated device, fewer or more metal layers may be required. A micro-fabrication technology similar to EFAB [8] at Microfabrica Inc. would be one possibility in creating the contemplated device. The EFAB manufacturing process begins with a blank substrate, typically a ceramic wafer, and grows devices layer-by-layer by depositing and precisely planarizing at least two metals. One metal is structural, forming the features of the finished device. The other metal is sacrificial, supporting the device during its fabrication. These processing steps are repeated until all layers have been formed and the desired device has been fully generated. The fabricated device is encapsulated within a block of sacrificial metal. Lastly, the sacrificial metal is completely removed by a highly selective etching process and thereby, freeing the device for use.

A DC or static magnetic field exists along the x-axis direction. An applied RF magnetic field anywhere between 10 MHz to 1 GHz is generated along the z-axis in the test sample by a coil in the contemplated device. A magnetic field gradient due to the ferromagnetic sample exists in the x-direction along with the resonant motion of the levitating micro-disk also occurring along the x-axis. A fiber-optic interferometer is used to both sense the oscillating motion of the levitating disk and the position of the ferromagnetic sample relative to the imaged test sample. This monitoring by the interferometer occurs via the reflection of light from the illustrated laser reflectors. Due to the cylindrical geometry of the contemplated device, the position of the test sample on the micro-disk can be vertically adjusted along the z-direction and rotated within the x-y plane. The position of the test sample on the micro-disk along the z-axis is monitored either by the use of an additional interferometer or by the use of an electrical sensing scheme, such as a capacitance sensor. Other directions of oscillatory motion of the micro-disk are possible. The direction of the micro-disk's motion is determined by the directions in which the DC magnetic field, the magnetic field gradient, and the RF field are applied.

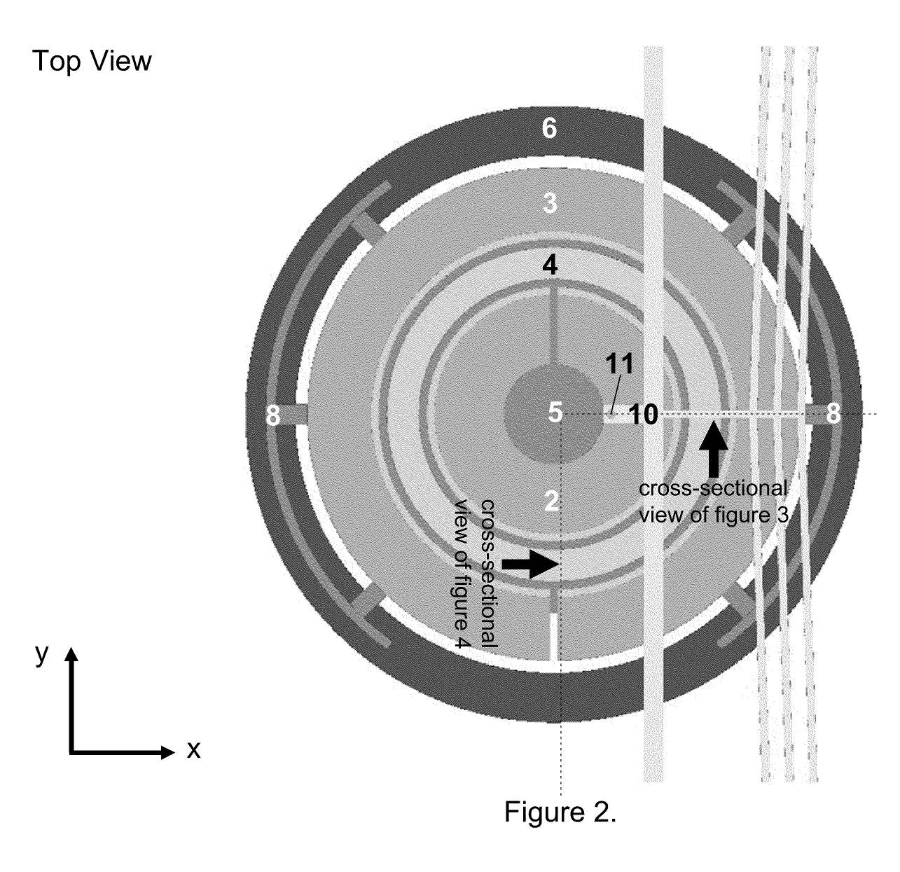

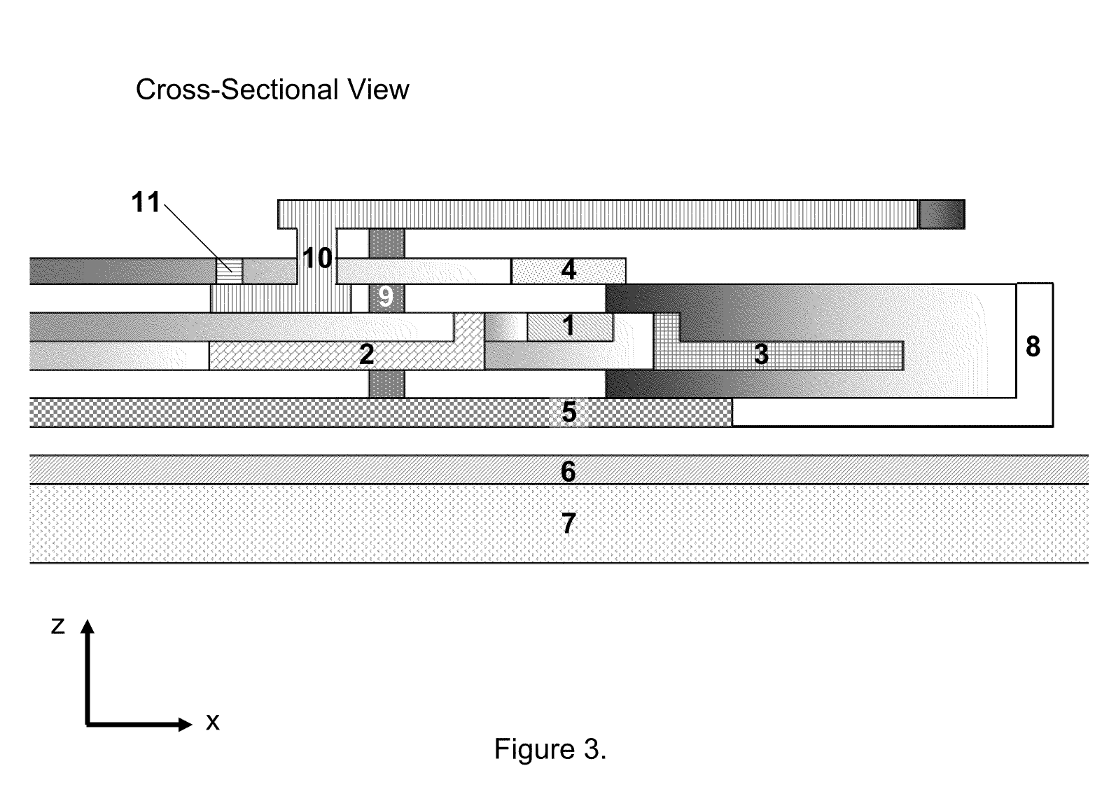

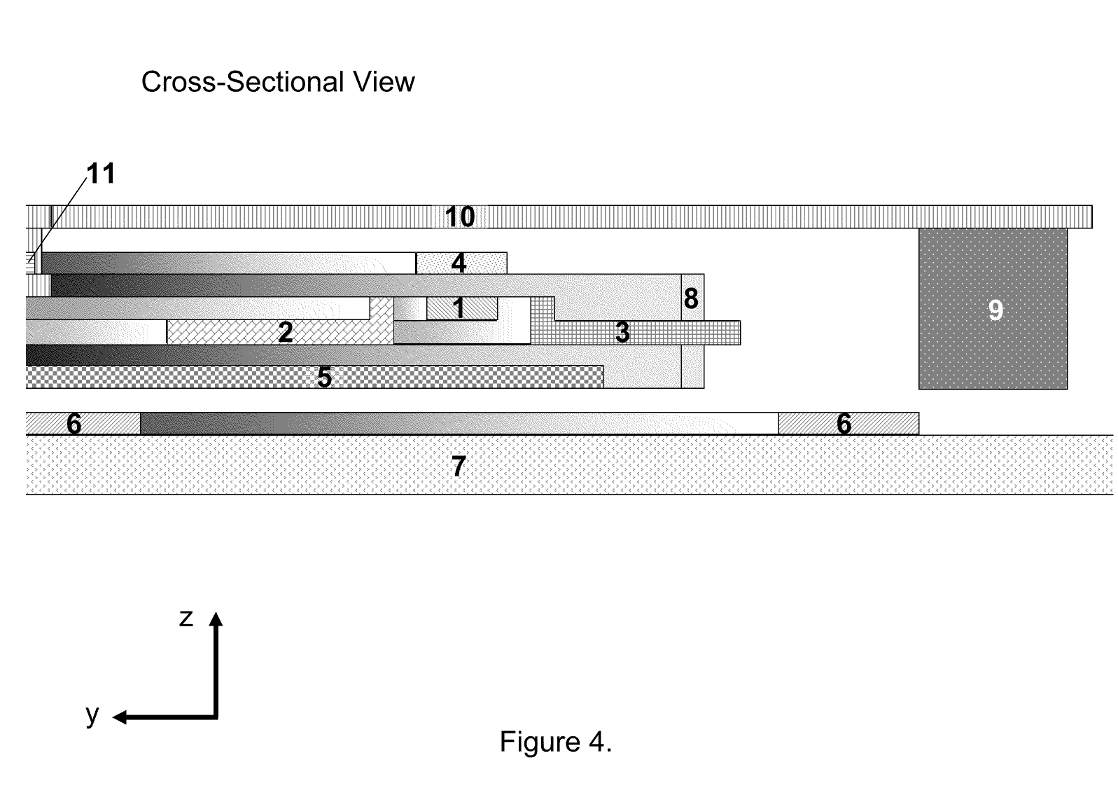

In FIG. 2, a view above the contemplated device without a test sample is shown. FIGS. 3 through 7 depict cross-sectional views of the device either with or without a test sample. Four metal electrodes, labeled as 1, 2, 3, and 4, lie above the levitating micro-disk, labeled as 5. The views shown in FIGS. 3 and 4 are substantially symmetric with the opposite portion of the embodiment. In FIG. 3, the symmetry exception relates to the inclusion of the micro-positioner reflector 9, the bent beam actuator 10 and the sample 11. Shading on some objects denotes that, when moving deeper into the cross-sectional plane (in FIG. 3, the x-z plane), the gray scale goes from white to black. Thereby, in the drawings, the darker regions generally lie deeper within the diagram.

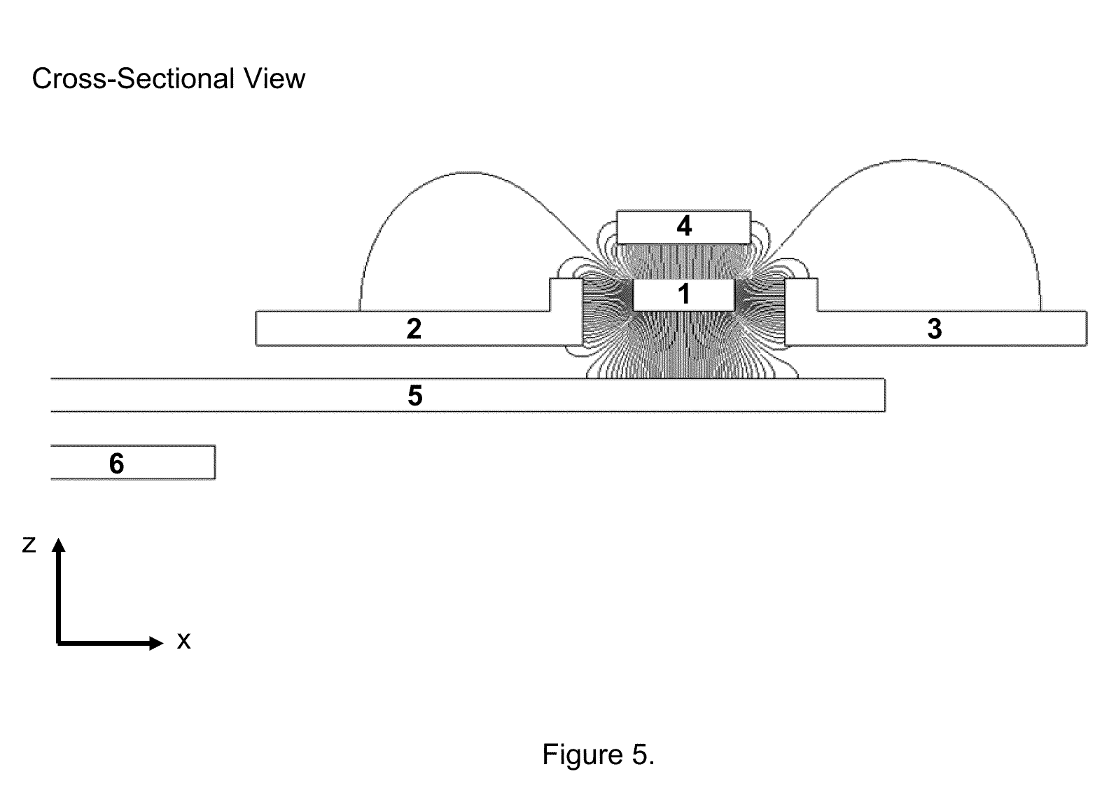

Before conducting an MRFM measurement with the contemplated device, the micro-disk 5 with a test sample is levitated in a self-stabilized manner (no feedback control is required). Electrode 1 is used to generate a vertical, attractive electrostatic force to lift the micro-disk 5 in the positive z-direction through the application of a DC voltage at this electrode. The minimum voltage required to generate enough lift to offset the force of gravity is given as V_{lift}. Stiction forces between the micro-disk 5 and the ground plane, labeled as 6, can be removed through the placement of dimples underneath the micro-disk 5 during fabrication (not shown in the illustrations) and by initially pulsing the amplitude of the voltage on electrode 1 such that the electrostatic forces overcome the stiction forces to lift the disk 5 off of the ground plane 6. The attractive electrostatic force varies inversely with the square of the distance between electrode 1 and the micro-disk 5. Before levitation, the micro-disk 5 lies in contact with the ground plane 6 and is at zero volts (0 V). Electrodes 2, 3, and 4 are assumed to be at a DC bias of 0 V. The electric field lines originating at electrode 1 are terminated at the surrounding grounded conductors (2 through 5) as shown in FIG. 5. Electrode 4 acts as a shield around electrode 1 to confine the electric field. The position of the disk 5 along the z-axis can be sensed by measuring the amount of capacitance that exists between electrode 1 and the disk 5.

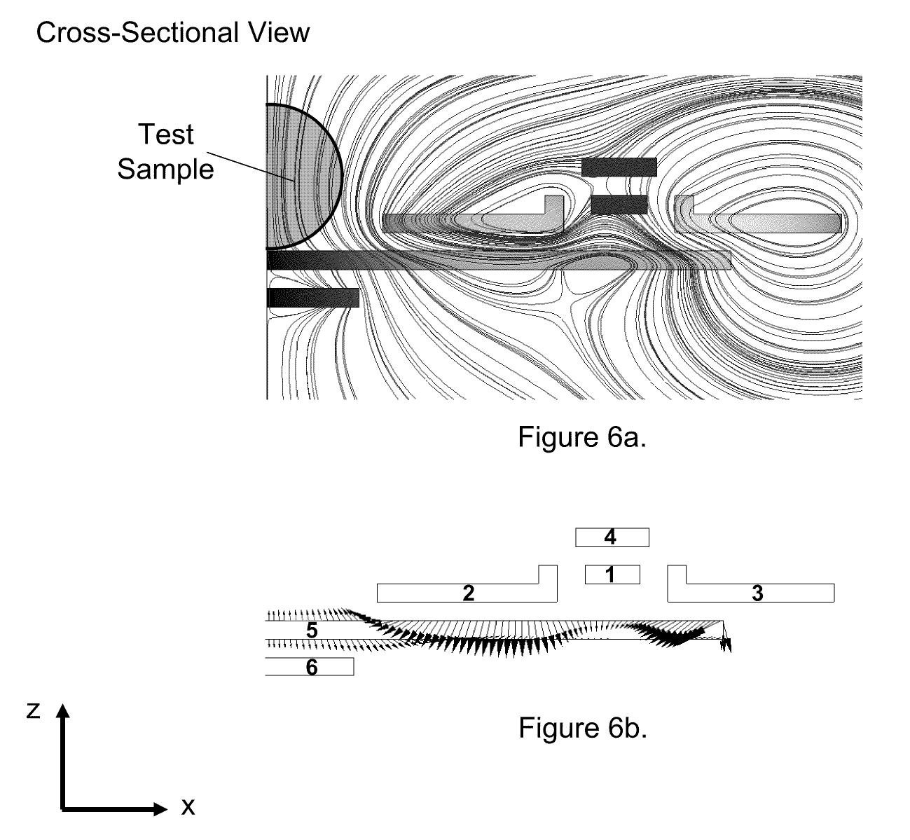

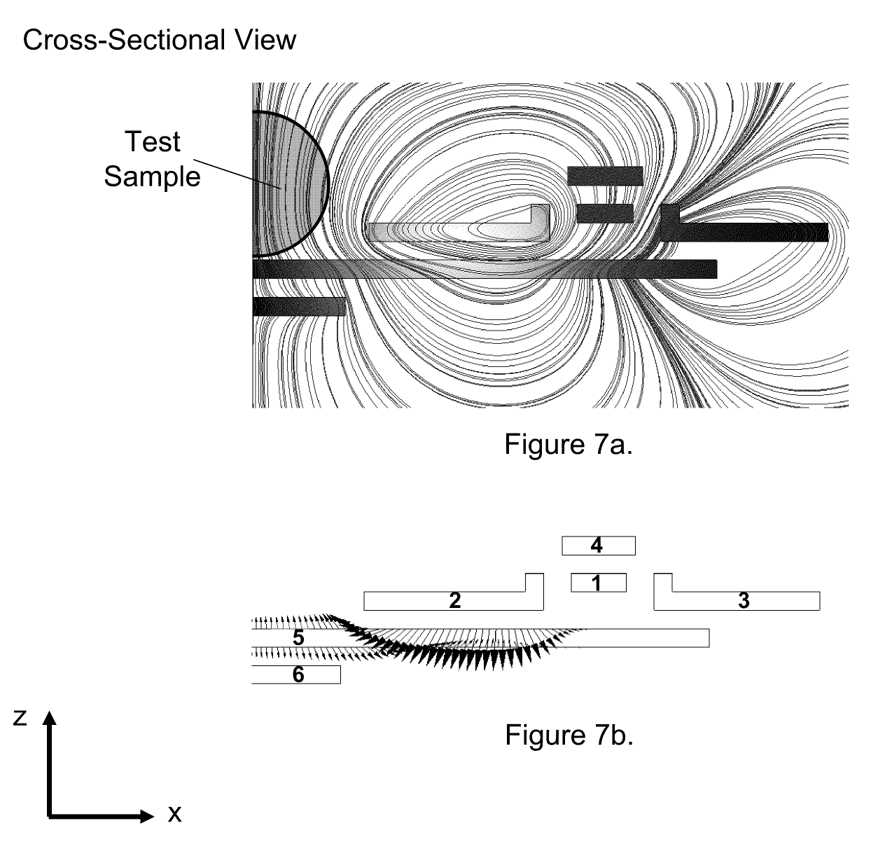

Through the application of RF currents in the two coils, denoted as electrodes 2 and 3, repulsive forces arise due to the interaction between the excitation currents in the coils and the induced eddy currents in the micro-disk 5 generated by Lenz's law. The position of the levitating disk 5 along the z-axis is determined by the amount of DC bias on electrode 1 and the magnitude and frequency of the RF currents in the coils 2, 3. Electrode 2 generates primarily a vertical repulsive force in the negative z-direction on the disk 5, and electrode 3 generates primarily a radially inward repulsive force on the disk 5 to constrain it within the x-y plane. This statement regarding the direction of the repulsive electromagnetic forces is illustrated in FIGS. 6 and 7. In FIG. 6b, the repulsive forces on the surfaces of the micro-disk 5 are shown for equal excitation currents in electrodes 2, 3 and at a frequency of 100 MHz. In FIG. 6b, the repulsive forces are depicted as arrows where the size of the arrow represents the magnitude of the force. Both vertically downward and radially inward force components are seen to dominate in FIG. 6b. In FIG. 7b, the excitation current is removed in electrode 3 and only exists in electrode coil 2. Consequently only a predominately downward force remains. The repulsive electromagnetic force varies inversely with the distance between the coils (electrodes 2, 3) and the micro-disk 5. For a given excitation current magnitude and frequency, as the DC bias on electrode 1 is increased, the micro-disk 5 moves upward along the z-axis and eventually the attractive electrostatic force (square law dependence on distance) causes an instability such that the micro-disk 5 would be pulled into the above electrodes (2, 3). At this “pull-in” voltage (here it is denoted as a pull-up voltage, Vₚᵤₗₗ₋ᵤₚ) the electrostatic forces overtake the restoring electromagnetic forces. Consequently, the position of the micro-disk 5 in the x, y, and z directions is stabilized only over a range of voltages between V_{lift} and Vₚᵤₗₗ₋ᵤₚ applied at electrode 1 for a given set of excitation current magnitudes and frequencies in the electrodes 2, 3.

In the contemplated device, an electrostatic force is chosen to lift the micro-disk 5 with the test sample since the magnitude of this lifting force grows as the square of the voltage on the controlling electrode and inversely with the square of the distance between the disk 5 and the controlling electrode. An electromagnetic force is used to stabilize the position of the disk 5 with the test sample. Thereby, as the mass of the disk 5 and/or test sample changes within the contemplated device, the electrostatic forces can be more easily adjusted to compensate for any changes in the gravitation forces. One prior device [5] employed electromagnetic forces to levitate an object while electrostatic forces were used if necessary for stabilization. However, in this prior approach, very large excitation current densities (10¹⁰ A/m²) applied at frequencies around 10 MHz were required to lift micro-scale objects. In addition, the large induced eddy current densities can cause significant heating within the levitated object. In the contemplated device, electromagnetic forces are used only to stabilize the position of the disk 5, and not to lift it. Thereby, the result is much smaller excitation currents and much smaller eddy currents leading to less heating within the levitated object.

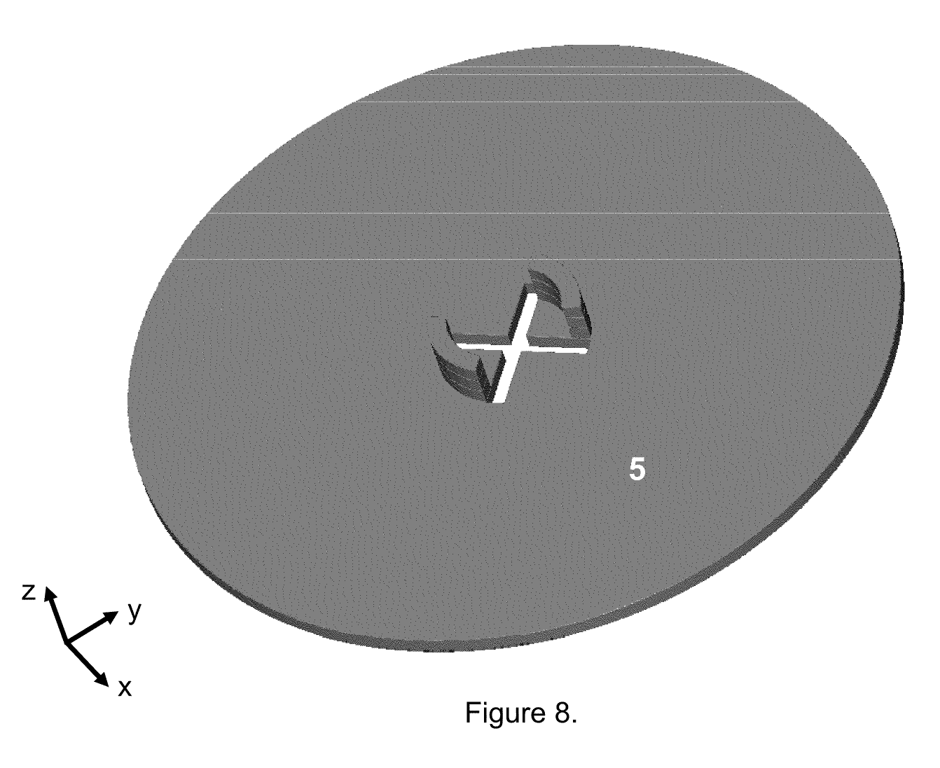

In the embodiment shown in FIG. 8, air slots forming an “X” are fabricated into the micro-disk 5. The test sample is placed on top of the disk, with the air slots serving to minimize any induced eddy currents and heating. Two curved wall sections (approximately 12 μm high) on the top of the micro-disk 5 provide both a means for sample containment and a mechanism to keep the micro-disk 5 and the test sample somewhat centered inside the controlling electrodes (1 through 3) before any voltages or currents are applied to these electrodes.

As stated previously, electrodes 2 and 3 generate RF magnetic fields within the test sample along the z-direction in the frequency range of 10 MHz to 1 GHz. The RF magnetic field lines are depicted in FIGS. 6a and 7a. Also in these figures, gray scale shading within the electrodes illustrates the magnitude of the current density where black equals zero and white equals the maximum value. Besides playing a role to stabilize the position of the micro-disk 5, these RF magnetic fields are used to satisfy the spin resonance condition within the test sample during a nuclear magnetic resonance (NMR) or an electron paramagnetic resonance (EPR) MRFM measurement. NMR measurements with the contemplated device are conducted at frequencies typically around 100 MHz and DC magnetic fields of 2 to 3 T (Tesla). EPR measurements with the contemplated device are conducted in the L-Band (few hundred MHz to 1 GHz) and for DC magnetic fields up to about 0.04 T.

In the contemplated device, the lower frequency limit of 10 MHz is selected for two reasons. First, this is the minimum frequency in which an NMR measurement is performed. Second, the magnitude of the repulsive electromagnetic forces at 10 MHz is sufficient for stabilization. The higher frequency limit of 1 GHz is also selected for two reasons. First, L-Band EPR is typically performed in the frequency range of 800 MHz to 1 GHz. Second, the skin depth of a non-ferromagnetic metal, such as gold, in the contemplated device at 1 GHz is about 2.8 μm. Thereby, at 1 GHz, about 70% of the micro-disk's 4 μm thickness has eddy currents induced within it, and a reasonable restoring force can still be generated to stabilize the position of the disk 5.

During an MRFM measurement, the resonator is driven with an oscillating force at its resonance frequency. In the contemplated device, the micro-disk 5 oscillates within the x-y plane during an MRFM measurement. Electrode 3 controls the lateral restoring force in the x-y plane, and thereby, controls the electrically tuned spring constant, k_{elec}, of the resonator. Before an MRFM measurement is conducted, the excitation current magnitude and frequency are adjusted in electrode 3 to center the position of the disk 5 and the test sample in the x-y plane. At the start of the MRFM measurement, the excitation current magnitude and frequency are adjusted in electrode 3 such that the laterally restoring forces in the x-y plane are decreased to a level in which k_{elec} is 1×10⁻⁶ N/m or less. For a disk made of non-ferromagnetic metal, such as gold, of radius 100 μm and thickness 4 μm, the mass of this disk is 2.4 nkg (nano-kilogams). If a test sample of negligible mass is added to the levitating disk, then the total mass (mₜₒₜ) to be levitated is approximately 2.4 nkg. The lateral resonance frequency (fₗₐₜ) of the disk with sample is given by the following equation:

$${f}_{lat} = \frac{1}{2 π} \sqrt{\frac{{k}_{elec}}{{m}_{tot}}} \qquad ( 1 )$$

For the contemplated device, the resonance frequency for oscillating motion of the micro-disk 5 in the x-y plane is as high as approximately 3 Hz for the above stated values.

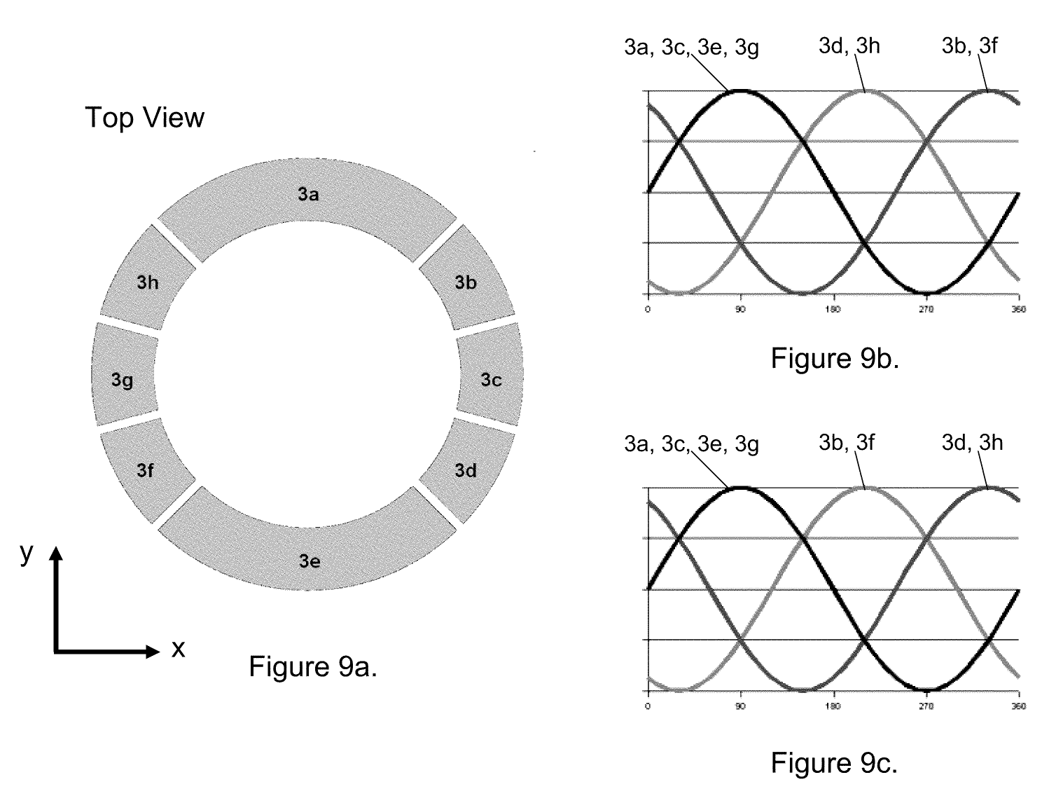

Instead of a single coil configuration for electrode 3, a multi-segmented coil is shown in FIG. 9a, where an azimuthal excitation current flows in each segment. The advantages of the segmented coil are two fold. First, the electrically controlled spring constant, k_{elec}, in the x-y plane is separated into two components, one in the x-direction, k_{elec,x}, and one in the y-direction, k_{elec,y}. For example, if current is applied to segments 3a and 3e in FIG. 9a, but not to the other segments, then k_{elec,y}>>k_{elec,x}. Second, poly-phase current signals can be applied to the segments to rotate the micro-disk in the x-y plane so that different cross-sections (or resonant slices) of the test sample can be imaged during an MRFM measurement. For example, if current signals of three phases (0°, 120°, and 240°) are applied to the segments, as shown in FIG. 9b, then the micro-disk is rotated in the counter-clockwise direction. However, if these three phases are applied, as shown in FIG. 9c, then the micro-disk 5 is rotated in the clockwise direction. Previously, a similar scheme [9] was used to produce rotation in an n-phase device, where the stator coil was split into “n” segments. In this prior work, a rotating magnetic flux pattern was produced in the radial coil component by temporally displacing the current in each segment by 2π/n and a motive torque was generated.

The following is a discussion on how an MRFM measurement in the contemplated device is conducted. Using a technique that has been conducted in prior MRFM measurements [10], the statistical polarization of the spins in a test sample in the contemplated device is measured by using a technique known as adiabatic rapid passage. In a DC magnetic field, the frequency of a transverse RF magnetic field is swept through the spin resonance condition. If the frequency sweep is performed slowly enough, then the adiabatic condition is met and the frequency sweep induces spin inversions along the direction of the DC magnetic field (this is the x-direction in the contemplated device). These inversions are detected using a ferromagnetic sample to generate a magnetic field gradient in the test sample and an ultrasensitive force detector (the levitated micro-disk 5). In an MRFM measurement in the contemplated device, the frequency of the RF magnetic field is swept through the spin resonance condition twice every period of oscillation, Tₗₐₜ, of the micro-disk 5, where Tₗₐₜ=1/fₗₐₜ. Thereby, the longitudinal component of the spins in the test sample flips at the frequency, fₗₐₜ. By measuring the amplitude of the micro-disk's lateral oscillation on resonance using an interferometer, the longitudinal component of the net spin polarization is determined. In the contemplated device, the RF magnetic field is swept over a narrow bandwidth (about 1% of the spin resonance frequency) by sweeping the frequency of the current in electrode 2. Thereby, the effects of this frequency modulation on the levitated position of the micro-disk along the z-axis are insignificant.

The present invention may be embodied in other specific forms without departing from the spirit and central attributes thereof. Accordingly, reference should be made to the appended claims, rather than the foregoing specification as indicating the scope of the invention.

### References Cited

[1] S. Eamshaw, “On the nature of the molecular forces which regulate the constitution of the luminferous ether,” Trans. Camb. Phil. Soc. 7, 97-112, 1842.
[2] M. Kraft, M. M. Farooqui, and A. G. R. Evans, “Modelling and design of an electrostatically levitated disc for inertial sensing applications,” J. Micromech. Microeng. 11, 423-427, 2001.
[3] R. Toda, N. Takeda, T. Murakoshi, S. Nakamura and M. Esashiy, “Electrostatically Levitated Spherical 3-Axis Accelerometer,” Proc IEEE Micro Electro Mech Syst MEMS, 710-713, 2002.
[4] M. J. Hennessy, “Cantilever-free magnetic resonance force microscope,” U.S. Pat. No. 6,836,112, Dec. 28, 2004.
[5] C. Shearwood, C. B. Williams, R. Barret-Yates and P. H. Mellor, “Levitation Systems,” U.S. Pat. No. 5,955,800, Sep. 21, 1999.
[6] D. Rugar, R. Budakian, H. J. Mamin and B. W. Chui, “Single spin detection by magnetic resonance force microscopy,” Nature 430, 329-332, 2004.
[7] L. Que, J-S Park and Y. B. Gianchandani, “Bent-beam electrothermal actuators: Part I. Single beam and cascaded devices,” IEEE/ASME J. MEMS 10, 247-254, 2001.
[8] http://www.microfabrica.com/pages/index.php?pg=technology.
[9] C. Shearwood, K. Y. Ho, C. B. Williams, and H. Gong, “Development of a levitated micromotor for application as a gyroscope,” Sensors and Actuators 83, 85-92, 2000.
[10] M. Poggioa, C. L. Degen, C. T. Rettner, H. J. Mamin, and D. Rugar, “Nuclear magnetic resonance force microscopy with a microwire RF source,” Appl. Phys. Lett. 90, 263111, 2007.

What is claimed is:

1. A Magnetic Resonance Force Microscopy (MRFM) system comprising:
a resonator having
a micro-disk for supporting a measurement sample,
a ferromagnetic sample positioned adjacent the micro-disk;
electrodes positioned adjacent the micro-disk and inducing an electrostatic field for lifting and levitating the micro-disk, the electrostatic field applying restoring forces on the micro-disk to stabilize levitation, and
means for measuring force variations between the micro-disk and measurement sample supported thereon and the ferromagnetic sample.

2. The MRFM system as in claim 1 wherein the measuring means measures the amplitude of lateral oscillations of the micro-disk and the measurement sample supported thereon that are generated by the forces applied by the ferromagnetic sample.

3. The MRFM system as in claim 2 wherein the measuring means is a fiber-optic interferometer.

4. The MRFM system as in claim 3 wherein the measuring by the interferometer is performed by reflection of light from reflectors associated with the micro-disk and a support for the ferromagnetic sample.

5. The MRFM system as in claim 4 wherein the ferromagnetic sample is supported on a micro-positioner.

6. The MRFM system as in claim 5 wherein the micro-positioner is in the form of a bent-beam electrothermal actuator.

7. The MRFM system as in claim 1 wherein the measuring means measures the force effects on the micro-disk along a longitudinal axis, as the disk is oscillated in an end to end rocking motion about a transverse axis.

8. The MRFM system as in claim 1 wherein the electrodes are formed by a multi-segmented coil.

9. The MRFM system as in claim 8 wherein the current signals within the multi-segmented coil rotates the micro-disk for cross-sectional sample exposure.

10. The MRFM system as in claim 9 wherein different phases of the current signals are applied to different segments of the multi-segmented coil causing micro-disk rotation.

11. The MRFM system as in claim 1 wherein the electrodes induce RF magnetic fields to satisfy sample spin resonance in order to achieve imaging of the measurement sample.

12. The MRFM system as in claim 1 wherein the electrodes comprise an off-chip or an on-chip RF wire that applies an RF magnetic field.

13. The MRFM system as in claim 1, wherein the electrodes apply a combination of RF current and DC bias from various positions about the micro-disk to stabilize the micro-disk.

14. The MRFM system as in claim 1 wherein the electrodes comprise DC biased electrodes to lift and levitate the micro-disk.

15. The MRFM system as in claim 14 wherein the electrodes comprise RF current electrodes that apply repulsive forces due to the interaction between the excitation currents in the coils and induced eddy currents in the micro-disk.

16. The MRFM system as in claim 15 wherein the electrodes comprise at least one retention electrode to constrain lateral movement of the micro-disk in it levitation plane.

17. The MRFM system as in claim 1 further comprising means for controlling the levitation of the micro-disk by the application of an electrostatic field, the electrostatic field creating a stabilized equilibrium for the micro-disk by the application of repulsive electromagnetic forces.

18. The MRFM system as in claim 1 wherein the micro-disk comprises air slots within its surface, the air slots formed to minimize induced eddy currents and heating within the movement of the micro-disk.

19. A magnetic resonance force microscope (MRFM) system comprising:
a levitating micro-disk having an electrically-controlled force sensitivity and a ratio of the spring constant (k) to the quality factor (Q) of the resonating micro-disk is less than about 1×10⁻⁸ N/m.

20. The MRFM system of claim 19 wherein an electrostatic field is employed to levitate a micro-disk and wherein the micro-disk is stabilized through the application of repulsive electromagnetic forces.
